(19) United States
(12) Patent Application Publication
(10) Pub. No.: US 2026/0026227 A1
(43) Pub. Date: Jan. 22, 2026

(54) DISPLAY DEVICE AND ELECTRONIC DEVICE

(71) Applicant: Samsung Display Co., Ltd., Yongin-si (KR)

(72) Inventors: Xinxing LI, Yongin-si (KR); Byung Hee CHOI, Yongin-si (KR); Jun Woo HYUNG, Yongin-si (KR)

(21) Appl. No.: 19/239,171

(22) Filed: Jun. 16, 2025

(30) Foreign Application Priority Data
Jul. 16, 2024 (KR) 10-2024-0093662

(51) Int. Cl. H10K 59/38; H10K 59/35; H10K 59/80

(52) U.S. Cl. CPC H10K 59/38; H10K 59/35; H10K 59/80515; H10K 59/8792

(57) ABSTRACT

A display device may include: a display area including a first pixel including a first sub-pixel, a second sub-pixel, and a third sub-pixel; a first light emitting element included in the first sub-pixel; a second light emitting element included in the second sub-pixel; and a third light emitting element included in the third sub-pixel. The first light emitting element may include a (1-1)th electrode, the second light emitting element may include a (1-2)th electrode, and the third light emitting element may include a (1-3)th electrode. The (1-1)th electrode may be spaced apart from the (1-2)th electrode at a (2-1)th distance, and the (1-2)th electrode may be spaced apart from the (1-3)th electrode at a (2-2)th distance equal to the (2-1)th distance.

### CROSS-REFERENCE TO RELATED APPLICATION

The present application claims priority under 35 U.S.C. § 119 (a) to and the benefit of Korean Patent Application No. 10-2024-0093662, filed on Jul. 16, 2024, in the Korean Intellectual Property Office, the entire content of which is hereby incorporated by reference.

### BACKGROUND

### 1. Field

Embodiments of the present disclosure generally relate to a display device and an electronic device.

### 2. Description of the Related Art

With the development of information technologies, the importance of a display device which is a connection medium between a user and information increases. Accordingly, research and development of display devices have been continuously conducted.

In general, a display device includes a plurality of pixels, which display an image. Each of the pixels may include an image display element (e.g., a light emitting element) provided in a pixel area, and the image display element may generate set or predetermined light, to thereby display an image.

Recently, a display device including light conversion layers has been developed to improve color purity. The light conversion layers may be above a light emitting element, and at least some of the light conversion layers convert light generated by the light emitting element into light having another wavelength. At least some of the light conversion layers include quantum dots to convert a wavelength of light.

### SUMMARY

Embodiments of the present disclosure provide a display device capable of simplifying manufacturing processes of the display device and securing a margin area to form light conversion layers including a quantum dot.

In accordance with an aspect of embodiments of the present disclosure, there is provided a display device including: a display area including a first pixel including a first sub-pixel, a second sub-pixel, and a third sub-pixel; a first light emitting element included in the first sub-pixel; a second light emitting element included in the second sub-pixel; and a third light emitting element included in the third sub-pixel, wherein the first light emitting element includes a (1-1)th electrode, the second light emitting element includes a (1-2)th electrode, and the third light emitting element includes a (1-3)th electrode, and wherein the (1-1)th electrode is spaced apart from the (1-2)th electrode at a (2-1)th distance, and the (1-2)th electrode is spaced apart from the (1-3)th electrode at a (2-2)th distance equal to the (2-1)th distance.

Each of the (1-1)th electrode, the (1-2)th electrode, and the (1-3)th electrode may be an anode electrode. The (1-1)th electrode, the (1-2)th electrode, and the (1-3)th electrode may each have the same shape.

The (1-1)th electrode, the (1-2)th electrode, and the (1-3)th electrode may each have the same area in a plan view.

The display device may further include a light conversion layer including: a first color conversion layer above the first light emitting element; a second color conversion layer above the second light emitting element; and a transmission layer above the third light emitting element. The first color conversion layer and the second color conversion layer may each have shapes that are point-symmetrical to each other.

The first color conversion layer may include: a (1-1)th portion that extends in a first direction and a second direction; a (1-2)th portion that extends in the second direction from the (1-1)th portion; and a (1-3)th portion that extends in the second direction from the (1-2)th portion. The (1-2)th portion may have a width widened in the second direction. Each of the first color conversion layer and the second color conversion layer may each have a shape that is symmetrical with respect to a line that extends in the second direction in a plan view.

The first color conversion layer may include: a (1-1)th portion that extends in a first direction and a second direction; and a (1-2)th portion that extends in the second direction from the (1-1)th portion. The (1-2)th portion may have a width that is wider than a width of the (1-1)th portion and is constant, or have a width widened in the second direction. Each of the first color conversion layer and the second color conversion layer may have a shape that is symmetrical with respect to a line that extends in the second direction in a plan view.

The display device may further include: a pixel circuit layer including a pixel circuit; a first contact hole that electrically connects the first light emitting element and the pixel circuit layer to each other; a second contact hole that electrically connects the second light emitting element and the pixel circuit layer to each other; and a third contact hole that electrically connects the third light emitting element and the pixel circuit layer to each other. The first contact hole and the second contact hole may be spaced apart from each other at a (1-1)th distance, and the second contact hole and the third contact hole may be spaced apart from each other at a (1-2)th distance equal to the (1-1)th distance.

The display device may further include a spacer under the light conversion layer. The spacer may be between the second color conversion layer and the transmission layer in a plan view.

The display device may further include: a second pixel provided with the first pixel in the first direction, the second pixel including a first adjacent sub-pixel, a second adjacent sub-pixel, and a third adjacent sub-pixel; and a spacer under the light conversion layer. The second pixel may include a first adjacent color conversion layer having the same structure as the first color conversion layer. The spacer may be between the transmission layer and the first adjacent color conversion layer in a plan view.

The display device may further include a light blocking layer on the light conversion layer. The light blocking layer may include: a first filter opening that defines a first emission area; a second filter opening that defines a second emission area; and a third filter opening that defines a third emission area. The first emission area, the second emission area, and the third emission area may have respective areas that are different from each other in a plan view.

In accordance with another aspect of embodiments of the present disclosure, there is provided a display device including: a display area including a first pixel including a first sub-pixel, a second sub-pixel, and a third sub-pixel; a first light emitting element included in the first sub-pixel; a second light emitting element included in the second sub-pixel; a third light emitting element included in the third sub-pixel; and a light conversion layer above the first to third light emitting elements, wherein the light conversion layer includes a first color conversion layer, a second color conversion layer, and a transmission layer, wherein the first color conversion layer and the second color conversion layer each have shapes that are point-symmetrical to each other in a plan view, and wherein each of the first color conversion layer and the second color conversion layer has a shape that is symmetrical with respect to a line that extends in one direction in a plan view.

The first light emitting element may include a (1-1)th electrode, the second light emitting element may include a (1-2)th electrode, and the third light emitting element may include a (1-3)th electrode. The (1-1)th electrode may be spaced apart from the (1-2)th electrode at a (2-1)th distance, and the (1-2)th electrode may be spaced apart from the (1-3)th electrode at a (2-2)th distance equal to the (2-1)th distance. Each of the (1-1)th electrode, the (1-2)th electrode, and the (1-3)th electrode may be an anode electrode.

The display device may further include: a pixel circuit layer including a pixel circuit; a first contact hole that electrically connects the first light emitting element and the pixel circuit layer to each other; a second contact hole that electrically connects the second light emitting element and the pixel circuit layer to each other; and a third contact hole that electrically connects the third light emitting element and the pixel circuit layer to each other. The first contact hole and the second contact hole may be spaced apart from each other at a (1-1)th distance, and the second contact hole and the third contact hole may be spaced apart from each other at a (1-2)th distance equal to the (1-1)th distance.

The first color conversion layer may include: a (1-1)th portion having a short side in a direction perpendicular (e.g., substantially perpendicular) to the one direction and a long side in the one direction; a (1-2)th portion having a trapezoidal shape having a width widened in the one direction; and a (1-3)th portion that extends in the one direction from the (1-2)th portion.

The first color conversion layer may include: a (1-1)th portion having a short side in a direction perpendicular (e.g., substantially perpendicular) to the one direction and a long side in the one direction; and a (1-2)th portion that extends in the one direction from the (1-1)th portion. The (1-2)th portion may have a width that is wider than a width of the (1-1)th portion and is constant, or have a width widened in the one direction.

The display device may further include a light blocking layer on the light conversion layer. The light blocking layer may include: a first filter opening that defines a first emission area; a second filter opening that defines a second emission area; and a third filter opening that defines a third emission area. At least a portion of the (1-2)th portion and at least a portion of the (1-3)th portion may not overlap with the first emission area in a plan view.

The first filter opening, the second filter opening, and the third filter opening may have respective areas that are different from each other in a plan view.

The at least a portion of the (1-2)th portion and the at least a portion of the (1-3)th portion may be provided at both sides of the first emission area in a plan view.

The display device may further include a spacer under the light conversion layer. The spacer may be between the second color conversion layer and the transmission layer in a plan view.

The display device may further include: a second pixel provided with the first pixel in the one direction, the second pixel including a first adjacent sub-pixel, a second adjacent sub-pixel, and a third adjacent sub-pixel; and a spacer under the light conversion layer. The second pixel may include a first adjacent color conversion layer having the same structure as the first color conversion layer. The spacer may be between the transmission layer and the first adjacent color conversion layer in a plan view.

An electronic device includes a processor to provide input image data; and a display device to display an image based on the input image data. The display device includes a display area including a first pixel including a first sub-pixel, a second sub-pixel, and a third sub-pixel; a first light emitting element included in the first sub-pixel; a second light emitting element included in the second sub-pixel; and a third light emitting element included in the third sub-pixel, wherein the first light emitting element includes a (1-1)th electrode, the second light emitting element includes a (1-2)th electrode, and the third light emitting element includes a (1-3)th electrode, and wherein the (1-1)th electrode is spaced apart from the (1-2)th electrode at a (2-1)th distance, and the (1-2)th electrode is spaced apart from the (1-3)th electrode at a (2-2)th distance equal to the (2-1)th distance.

### BRIEF DESCRIPTION OF THE DRAWINGS

Example embodiments of the present disclosure will now be described more fully hereinafter with reference to the accompanying drawings; however, the subject matter of the present disclosure may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic plan view illustrating a display device in accordance with an embodiment of the present disclosure.

FIG. 2 is a schematic plan view illustrating an arrangement of a pixel in accordance with an embodiment of the present disclosure.

FIG. 3 is a cross-sectional view illustrating a display device in accordance with an embodiment of the present disclosure.

FIG. 4 is an enlarged view illustrating a light conversion layer in accordance with an embodiment of the present disclosure.

FIG. 5 is a cross-sectional view schematically illustrating a display device in accordance with an embodiment of the present disclosure.

FIG. 6 is a schematic plan view of a pixel in accordance with a first embodiment of the present disclosure.

FIG. 7 is a schematic plan view of a pixel in accordance with a second embodiment of the present disclosure.

FIG. 8 is a schematic plan view of a pixel in accordance with a third embodiment of the present disclosure.

FIG. 9 is a plan view schematically illustrating an arrangement of a spacer in accordance with an embodiment of the present disclosure.

FIG. 10 is a plan view schematically illustrating an arrangement of the spacer in accordance with another embodiment of the present disclosure.

FIG. 11 is a block diagram of an electronic device according to an embodiment.

FIG. 12 shows schematic views of various embodiments of an electronic device.

### DETAILED DESCRIPTION

The subject matter of the present disclosure may accommodate various suitable changes and different shapes, and therefore, the present disclosure illustrates embodiments of the present disclosure in more detail with regard to particular examples. However, the examples are not limited to certain shapes an may accommodate all suitable changes and equivalent materials and replacements. The included drawings are illustrated in a fashion where the figures may be expanded for better understanding of the subject matter of the present disclosure.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the spirit and scope of the present disclosure. As used herein, the singular forms are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is between the element and the other element. An expression that an element such as a layer, region, substrate or plate is placed “beneath” or “below” another element indicates not only a case where the element is placed “directly beneath” or “just below” the other element but also a case where a further element is between the element and the other element.

The present disclosure generally relates to a display device. Hereinafter, a display device in accordance with an embodiment of the present disclosure will be described with reference to the accompanying drawings.

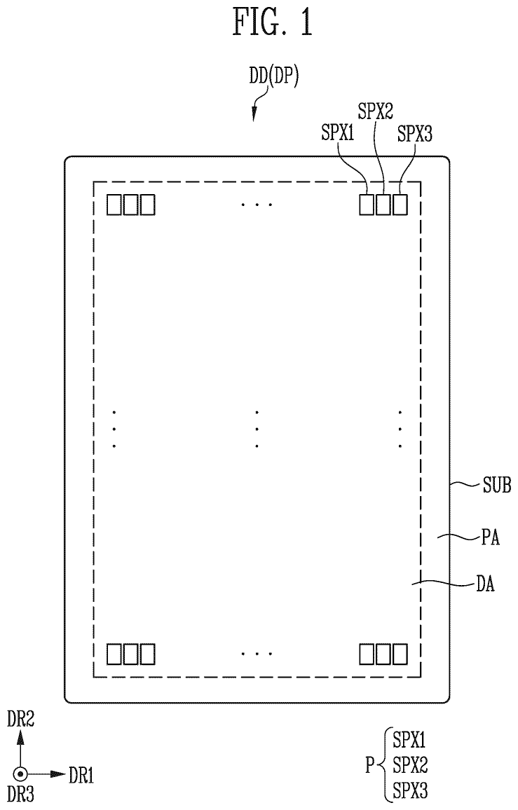

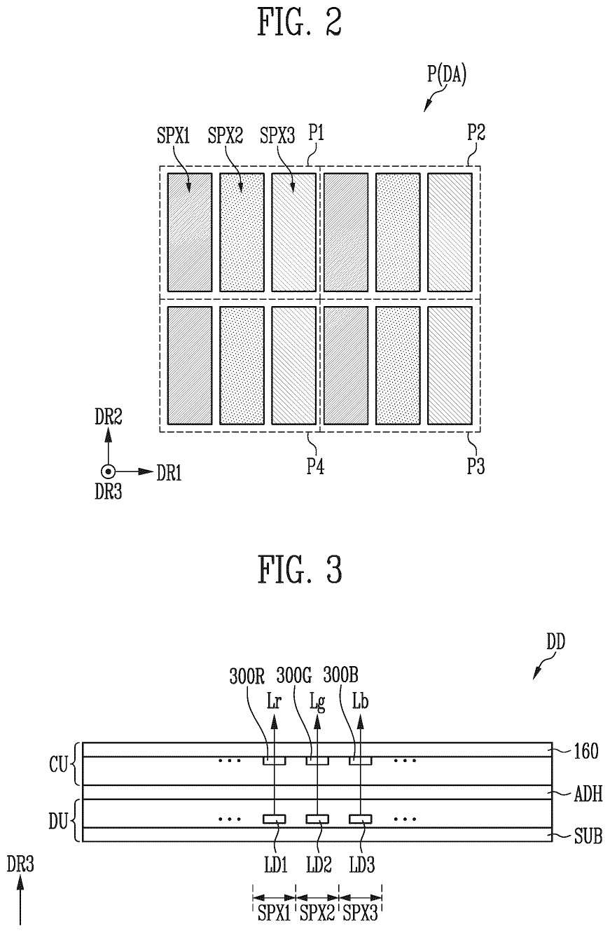

FIG. 1 is a schematic plan view illustrating a display device in accordance with an embodiment of the present disclosure. FIG. 2 is a schematic plan view illustrating an arrangement of a pixel in accordance with an embodiment of the present disclosure.

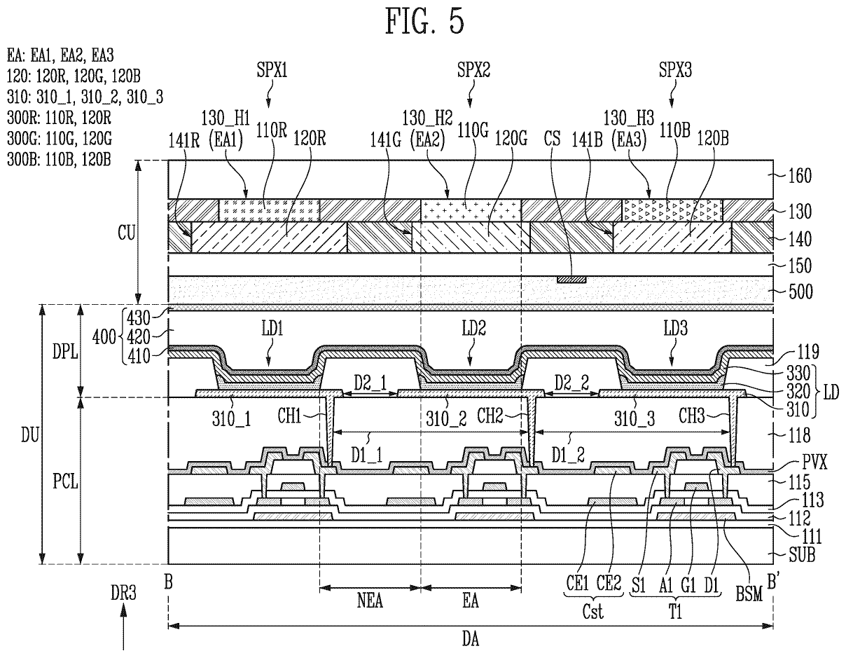

Referring to FIGS. 1-2, a display panel DP (or a display device DD) may display an image. The display panel DP may include a light emitting element LD (see FIG. 5). Self-luminescent display panels, such as an Organic Light Emitting Display panel (OLED panel) using an organic light emitting diode as a light emitting element, a micro-LED and/or nano-LED display panel using a micro LED and/or nano LED as a light emitting element, and a Quantum Dot Organic Light Emitting Display panel (QD OLED panel) using a quantum dot and an organic light emitting diode, may be used as the display panel DP. In embodiments, non-luminescent display panels, such as a Liquid Crystal Display panel (LCD panel), an Electro-Phoretic Display panel (EPD panel), and/or an Electro-Wetting Display panel (EWD panel), may be used as the display panel DP. When a non-luminescent display panel is used as the display panel DP, the display device DD may include a backlight unit which supplies light to the display panel DP. However, the present disclosure is not limited to a specific example. Hereinafter, in the present disclosure, an embodiment in which a Quantum Dot Organic Light Emitting Display panel (QD OLED panel) is used as the display panel DP will be described, but the present disclosure is not limited thereto.

The display panel DP may include a substrate SUB and pixels P on the substrate SUB.

The substrate SUB may include a transparent insulating material (e.g., a transparent electrically insulating material) to enable light to be transmitted therethrough. The substrate SUB may be a rigid substrate or a flexible substrate. The rigid substrate may be, for example, one selected from among a glass substrate, a quartz substrate, a glass ceramic substrate, and a crystalline glass substrate.

The flexible substrate may be one selected from among a film substrate and a plastic substrate, which include a polymer organic material. For example, the flexible substrate may include at least one selected from among polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

The display device DD (or the display panel DP) may have various suitable shapes. In an example, the display device DD may be provided in a rectangular shape, but the present disclosure is not limited thereto. For example, the display device DD may have a circular or elliptical shape (e.g., a generally circular or generally elliptical shape). Also, the display device DD may include an angular corner and/or a curved corner. For convenience, in FIG. 1, it is illustrated that the display device DD has a rectangular plate shape. Also, in FIG. 1, an extending direction of a short side of the display device DD (e.g., a lateral direction) (or a horizontal direction as a “row” direction of the pixel P) is indicated as a first direction DR1, and an extending direction of a long side of the display device DD (e.g., a longitudinal direction) (or a “column” direction of the pixel P) is indicated as a second direction DR2. In embodiments, a display direction of the display device DD or a normal of a plane on which the substrate SUB is provided is indicated as a third direction DR3.

The substrate SUB (and the display device DD) may include a display area DA to display an image and a peripheral area PA (or non-display area) surrounding the display area DA (or except the display area DA). The substrate SUB may include the display area DA including pixel areas in which the respective pixels P are provided and the peripheral area PA provided at the periphery of the display area DA (or adjacent to the display area DA).

The peripheral area PA may be adjacent to the display area DA. The peripheral area PA may be provided at at least one side of the display area DA. In an example, the peripheral area PA may surround a periphery (e.g., a circumference or edge) of the display area DA. In an example, the peripheral area PA may be a bezel area of the display device DD.

The pixels P may be provided in the display area DA on the substrate SUB. The peripheral area PA may be provided at the periphery of the display area DA. A structure that protects components included in the pixels P provided in the display area DA may be provided in the peripheral area PA, but the present disclosure is not limited thereto. For example, a line unit connected to the pixels P and a driving unit connected to the line unit to drive the pixels P may be provided in the peripheral area PA.

The pixel P may include a first pixel P1, a second pixel P2, a third pixel P3, and a fourth pixel P4. The first pixel P1, the second pixel P2, the third pixel P3, and the fourth pixel P4 may be provided in the display area DA. The display area DA may include a first pixel area in which the first pixel P1 is provided, a second pixel area in which the second pixel P2 is provided, a third pixel area in which the third pixel P3 is provided, and a fourth pixel area in which the fourth pixel P4 is provided.

The second pixel P2 may be adjacent to the first pixel P1. For example, the second pixel P2 along with the first pixel P1 may be provided in the first direction DR1. The third pixel P3 may be adjacent to the second pixel P2. For example, the third pixel P3 along with the second pixel P2 may be provided in the second direction DR2. The fourth pixel P4 may be adjacent to the third pixel P3. For example, the fourth pixel P4 along with the third pixel P3 may be provided in the first direction DR1. The first pixel P1, the second pixel P2, the third pixel P3, and the fourth pixel P4 may be provided clockwise. In the present disclosure, each of the first pixel P1, the second pixel P2, the third pixel P3, and the fourth pixel P4 may be provided according to a stripe arrangement.

Each of the first pixel P1, the second pixel P2, the third pixel P3, and the fourth pixel P4 may include a plurality of sub-pixels SPX1, SPX2, and SPX3. The display area DA may include a first sub-pixel area in which the first sub-pixel SPX1 is provided, a second sub-pixel area in which the second sub-pixel SPX2 is provided, and a third sub-pixel area in which the third sub-pixel SPX3 is provided. In an example, the first pixel P1 may include a first sub-pixel SPX1, a second sub-pixel SPX2, and a third sub-pixel SPX3. The first sub-pixel SPX1, the second sub-pixel SPX2, and the third sub-pixel SPX3 may be sequentially provided in the first direction DR1. However, the present disclosure is not limited thereto, and the first sub-pixel SPX1, the second sub-pixel SPX2, and the third sub-pixel SPX3 may be sequentially provided in the second direction DR2 crossing (e.g., intersecting) the first direction DR1.

The first to third sub-pixels SPX1, SPX2, and SPX3 may emit lights of different colors. In an example, the first sub-pixel SPX1 may emit a first light, the second sub-pixel SPX2 may emit a second light, and the third sub-pixel SPX3 may emit a third light. The first light may be light in a red wavelength band, the second light may be light in a green wavelength band, and the third light may be light in a blue wavelength band. The red wavelength band may be a wavelength band of about 600 nm to about 750 nm, the green wavelength band may be a wavelength band of about 480 nm to about 560 nm, and the blue wavelength band may be a wavelength band of about 370 nm to about 460 nm. However, embodiments of the present disclosure are not limited thereto. The colors, kinds, and/or numbers of sub-pixels constituting the pixel P are not particularly limited. In an example, the color of light emitted from each of the first to third sub-pixels SPX1, SPX2, and SPX3 may be variously and suitably changed. Hereinafter, when first to third sub-pixels SPX1, SPX2, and SPX3 are inclusively designated, the first to third sub-pixels SPX1, SPX2, and SPX3 may be designated as a pixel P.

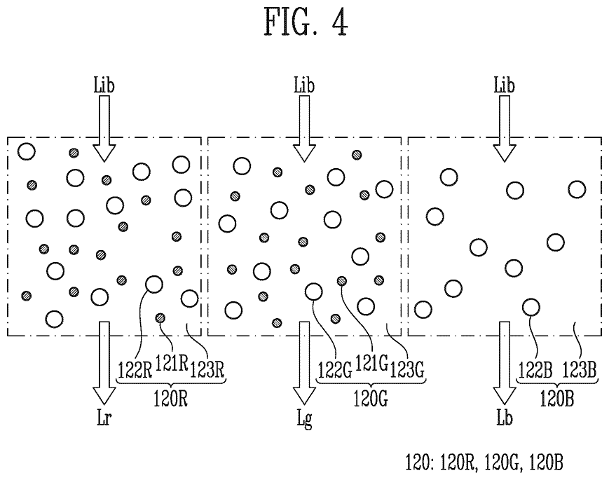

FIG. 3 is a cross-sectional view illustrating a display device in accordance with an embodiment of the present disclosure. FIG. 4 is an enlarged view illustrating a light conversion layer in accordance with an embodiment of the present disclosure. FIG. 4 is an enlarged view illustrating a light conversion layer 120 (color conversion layers 120R and 120G and a transmission layer 120B).

Referring to FIG. 3, the display device DD may include a display unit DU and a color filter unit CU provided while facing the display unit DU. The display unit DU may include a first sub-pixel SPX1, a second sub-pixel SPX2, and a third sub-pixel SPX3, which are on a substrate SUB. The first sub-pixel SPX1, the second sub-pixel SPX2, and the third sub-pixel SPX3 may be pixels that emit light of different colors on the substrate SUB. For example, the first sub-pixel SPX1 may emit red light Lr, the second sub-pixel SPX2 may emit green light Lg, and the third sub-pixel SPX3 may emit blue light Lb.

The first sub-pixel SPX1, the second sub-pixel SPX2, and the third sub-pixel SPX3 may include a first light emitting element LD1, a second light emitting element LD2, and a third light emitting element LD3, respectively. In an embodiment, each of the first light emitting element LD1, the second light emitting element LD2, and the third light emitting element LD3 may emit blue light. In another embodiment, the first light emitting element LD1, the second light emitting element LD2, and the third light emitting element LD3 may emit red light, green light, and blue light, respectively.

The color filter unit CU may include filter portions 300R, 300G, and 300B. Lights emitted from the first light emitting element LD1, the second light emitting element LD2, and the third light emitting element LD3 may be respectively emitted as the red light Lr, the green light Lg, and the blue light Lb while passing through the filter portions 300R, 300G, and 300B.

The filter portions 300R, 300G, and 300B may be provided immediately on/under an upper substrate 160. For example, the filter portions 300R, 300G, and 300B may be provided under the upper substrate 160. The filter portions 300R, 300G, and 300B may include a first color conversion layer 120R and a first filter layer 110R, a second color conversion layer 120G and a second filter layer 110G, and a transmission layer 120B and a third filter layer 110B, respectively.

The term “being provided immediately on/under the upper substrate 160” may mean that the color filter unit CU is manufactured by forming the first to third filter layers 110R, 110G, and 110B directly on the upper substrate 160. After that, the display unit DU and the color filter unit CU may be bonded to each other by allowing the first to third filter layers 110R, 110G, and 110B to respectively face the first sub-pixel SPX1, the second sub-pixel SPX2, and the third sub-pixel SPX3. In FIG. 3, it is illustrated that the display unit DU and the color filter unit CU are bonded to each other through an adhesive layer ADH. The adhesive layer ADH may be, for example, an Optical Clear Adhesive (OCA), but the present disclosure is not necessarily limited thereto. In another embodiment, the adhesive layer ADH may be omitted.

Referring to FIG. 4, the display device DD may include a light conversion layer 120. The light conversion layer 120 may include the first and second color conversion layers 120R and 120G and the transmission layer 120B. The first and second color conversion layers 120R and 120G may include a quantum dot material (e.g., a quantum dot). A core of the quantum dot may be selected from a Group II-VI compound, a Group III-V compound, a Group IV-VI compound, a Group IV element, a Group IV compound, and any combination thereof.

The Group II-VI compound may be selected from the group consisting of: a binary compound selected from the group consisting of CdSe, CdTe, ZnS, ZnSe, ZnTe, ZnO, HgS, HgSe, HgTe, MgSe, MgS, and any suitable mixture thereof; a ternary compound selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and any suitable mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and any suitable mixture thereof.

The Group III-V compound may be selected from the group consisting of: a binary compound selected from the group consisting of GaN, GaP, GaAs, GaSb, AlN, AlP, AlAs, AlSb, InN, InP, InAs, InSb, and any suitable mixture thereof; a ternary compound selected from the group consisting of GaNP, GaNAs, GaNSb, GaPAS, GaPSb, AlNP, AlNAs, AlNSb, AlPAS, AlPSb, INGaP, InNP, InNAs, InNSb, InPAs, InPSb, GaAlNP, and any suitable mixture thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and any suitable mixture thereof.

The Group IV-VI compound may be selected from the group consisting of: a binary compound selected from the group consisting of SnS, SnSe, SnTe, PbS, PbSe, PbTe, and any suitable mixture thereof; a ternary compound selected from the group consisting of SnSeS, SnSeTe, SnSTe, PbSeS, PbSeTe, PbSTe, SnPbS, SnPbSe, SnPbTe, and any suitable mixture thereof; and a quaternary compound selected from the group consisting of SnPbSSe, SnPbSeTe, SnPbSTe, and any suitable mixture thereof.

The Group IV element may be selected from the group consisting of Si, Ge, and any suitable mixture thereof. The Group IV compound may be a binary compound selected from the group consisting of SiC, SiGe, and any suitable mixture thereof.

A binary compound, a ternary compound, or a quaternary compound may exist in a particle with a uniform (e.g., substantially uniform) concentration distribution or exist in the same particle with partially different concentration distributions. In embodiments, the quantum dot may have a core-shell structure in which one quantum dot surrounds another quantum dot. An interface between a core and a shell may have a concentration gradient in which the concentration of an element existing in the shell becomes lower along a direction toward the center thereof.

In some embodiments, the quantum dot may have the above-described core-shell structure including a core having nanocrystals and a shell surrounding the core. The shell of the quantum dot may serve as a protective layer to prevent or reduce chemical deformation of the core thereby maintaining semiconductor properties, and/or serve as a charging layer for imparting or improving electrophoresis properties to the quantum dot. The shell may be a single layer or a multiple-layer. An interface between a core and a shell may have a concentration gradient in which the concentration of an element existing in the shell becomes lower along a direction toward the center thereof. An example of the shell of the quantum dot may include a metal and/or non-metal oxide, a semiconductor compound, or any combination thereof.

For example, the metal and/or non-metal oxide may be a binary compound such as SiO₂, Al₂O₃, TiO₂, ZnO, MnO, Mn₂O₃, Mn₃O₄, CoO, Co₃O₄, and/or NiO, and/or a ternary compound such as MgAl₂O₄, CoFe₂O₄, NiFe₂O₄, and/or CoMn₂O₄, but the present disclosure in not limited thereto.

In addition, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the present disclosure is not limited thereto.

The quantum dot may have a full width of half maximum (FWHM) of a light emission wavelength spectrum of about 45 nm or less, for example, about 40 nm or less, or about 30 nm or less. The color purity and/or color reproducibility may be improved in the above-described ranges. In embodiments, because light emitted through such a quantum dot is emitted in all (e.g., substantially all) directions, a wide viewing angle can be improved.

Although the form of the quantum dot is not particularly limited and may be any suitable form available in the art. In embodiments, quantum dots in forms of a spherical, pyramidal, and/or multi-arm shape, and/or cubic nanoparticles, nanotubes, nanowires, nanofibers, nanoparticles, and/or the like may be used as the quantum dot.

The quantum dot may control the color of emitted light according to the particle size thereof. Accordingly, the quantum dot may have various suitable light emission colors such as blue, red, and green.

The first color conversion layer 120R may convert blue incident light Lib (e.g., light emitted from the first light emitting element LD1) into light Lr of a first color. The light Lr of the first color may be the red light. The first color conversion layer 120R may include first quantum dots 121R and a first photosensitive polymer 123R in which first scattering particles 122R (e.g., first light scattering particles 122R) are dispersed.

The first quantum dots 121R may be excited by the blue incident light Lib to isotropically emit the light Lr of the first color, which has a wavelength longer than a wavelength of the blue light. The first photosensitive polymer 123R may be an organic material having light transmissivity. The first scattering particles 122R may scatter blue incident light Lib which is not absorbed into the first quantum dots 121R, thereby allowing more first quantum dots 121R to be excited, so that the color conversion rate of the first color conversion layer 120R can be increased. The first scattering particles 122R may be, for example, titanium oxide (TiO₂), a metal particle, and/or the like.

The second color conversion layer 120G may convert blue incident light Lib (e.g., light emitted from the second light emitting element LD2) into light Lg of a second color. The light Lg of the second color may be the green light. The second color conversion layer 120G may include second quantum dots 121G and a second photosensitive polymer 123G in which second scattering particles 122G (e.g., second light scattering particles 122G) are dispersed.

The second quantum dots 121G may be excited by the blue incident light Lib to isotropically emit the light Lg of the second color, which has a wavelength longer than the wavelength of the blue light. The second photosensitive polymer 123G may be an organic material having light transmissivity, and be the same material as the first photosensitive polymer 123R. The second scattering particles 122G may scatter blue incident light Lib which is not absorbed into the second quantum dots 121G, thereby allowing more second quantum dots 121G to be excited, so that the color conversion rate of the second color conversion layer 120G can be increased. The second scattering particles 122G may be, for example, titanium oxide (TiO₂), a metal particle, and/or the like, and be the same material as or a material different from the first scattering particles.

The transmission layer 120B may allow blue incident light Lib (e.g., light emitted from the third light emitting element LD3) to be transmitted therethrough, thereby emitting the blue incident light Lib toward the upper substrate 160. The transmission layer 120B may include a third photosensitive polymer 123B in which third scattering particles 122B (e.g., third light scattering particles 122B) are dispersed. The third photosensitive polymer 123B may be, for example, an organic material having light transmissivity, such as silicon resin and/or epoxy resin, and be the same material as or a material different from the first and second photosensitive polymers 123R and 123G. The third scattering particles 123 may scatter blue incident light Lib, thereby emitting the blue incident light Lib, and be the same material as or a material different from the first and second scattering particles 122R and 122G.

FIG. 5 is a sectional view schematically illustrating a display device in accordance with an embodiment of the present disclosure. FIG. 5 illustrates in more detail the display device DD as compared with the cross-sectional view shown in FIG. 3.

Referring to FIG. 5, at least one transistor T1 and a display element (e.g., a light emitting element LD) may be on a display area DA of the display device DD in accordance with embodiments of the present disclosure.

In this embodiment, the display area DA may include a plurality of sub-pixels SPX1, SPX2, and SPX3, and each of the sub-pixels SPX1, SPX2, and SPX3 may include an emission area EA. For example, a first sub-pixel SPX1 may include a first emission area EA1, a second sub-pixel SPX2 may include a second emission area EA2, and a third sub-pixel SPX3 may include a third emission area EA3. The emission area EA may be an area in which light is generated to be output (e.g., emitted) to the outside of the display device DD. A non-emission area NEA may be provided in the emission areas EA, so that the emission areas EA of the sub-pixels SPX1, SPX2, and SPX3 may be divided by the non-emission area NEA.

In the display area DA shown in FIG. 5, a driving transistor T1 and a storage capacitor Cst in a pixel circuit of each pixel P are illustrated. A display unit DU may include a pixel circuit layer PCL including the pixel circuit including the driving transistor T1 and the storage capacitor Cst and a display element layer DPL which includes the light emitting element LD and is on the pixel circuit layer PCL.

A first buffer layer 111 may be on a substrate SUB. A barrier layer may be further included between the substrate SUB and the first buffer layer 111. The barrier layer may function to prevent, minimize, or reduce infiltration of an impurity from the substrate SUB and/or the like into a semiconductor layer A1. The barrier layer may include an inorganic material such as oxide and/or nitride, an organic material, and/or an organic/inorganic compound, and be provided in a single-layer or multi-layer structure of an inorganic material and an organic material.

A bias electrode BSM may be on the first buffer layer 111 to correspond to the driving transistor T1. A voltage may be applied to the bias electrode BSM. In embodiments, the bias electrode BSM may function to prevent or reduce incidence of external light to the semiconductor layer A1. Accordingly, characteristics of the driving transistor T1 can be stabilized. In some embodiments, the bias electrode BSM may be omitted. A second buffer layer 112 may be over the bias electrode BSM.

The semiconductor layer A1 may be on the second buffer layer 112. The semiconductor layer A1 may include amorphous silicon and/or include poly-silicon. In another embodiment, the semiconductor layer A1 may include oxide of at least one material selected from the group consisting of indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), a cerium (Ce), and zinc (Zn). In some embodiments, the semiconductor layer A1 may be formed of, as a Zn oxide-based material, Zn oxide, In—Zn oxide, Ga—In—Zn oxide, and/or the like. In still another embodiment, the semiconductor layers A1 may be a IGZO In—Ga—Zn—O (IGZO), In—Sn—Zn—O (ITZO) and/or In—Ga—Sn—Zn—O (IGTZO) semiconductor in which metal such as In, Ga, and/or Sn is contained in ZnO. The semiconductor layer A1 may include a channel region, and a source region and a drain region, which are provided at both sides of the channel region. The semiconductor layer A1 may be configured as a single layer or a multi-layer.

A gate electrode G1 may be on the semiconductor layer A1 with the semiconductor layer A1 with a gate insulating layer 113 therebetween to at least partially overlap the semiconductor layer A1. The gate electrode G1 may include molybdenum (Mo), aluminum (Al), copper (Cu), titanium (Ti), and/or the like, and be provided as a single layer or a multi-layer. In an example, the gate electrode G1 may be a single layer of Mo. A first capacitor electrode CE1 of the storage capacitor Cst may be provided in the same layer as the gate electrode G1. The first capacitor electrode CE1 may be formed of the same material as the gate electrode G1.

An interlayer insulating layer 115 (e.g., an interlayer electrically insulating layer 115) may be provided to cover the gate electrode G1 and the first capacitor electrode CE1 of the storage capacitor Cst. The interlayer insulating layer 115 may include silicon oxide (SiₓO_{y}), silicon nitride (SiₓN_{y}), silicon oxynitride (SiₓO_{y}N_{z}), aluminum oxide (AlₓO_{y}), titanium oxide (TiₓO_{y}), tantalum oxide (TaₓO_{y}), hafnium oxide (HfₓO_{y}), zinc oxide (ZnₓO_{y}), and/or the like.

A second capacitor electrode CE2 of the storage capacitor Cst, a source electrode S1, and a drain electrode D1 may be on the interlayer insulating layer 115.

The second capacitor CE2 of the storage capacitor Cst, the source electrode S1, and the drain electrode D1 may include a conductive material (e.g., an electrically conductive material) including molybdenum (Mo), aluminum (Al), copper (Cu), titanium (Ti), and/or the like, and be formed as a multi-layer or a single layer, which includes the above-described material. In an example, the second capacitor electrode CE2, the source electrode S1, and the drain electrode D1 may be provided in a multi-layer structure of Ti/Al/Ti. The source electrode S1 and the drain electrode D1 may be connected to the source region and the drain region of the semiconductor layer A1 through contact holes, respectively.

The second capacitor electrode CE2 of the storage capacitor Cst may overlap with the first capacitor electrode CE1 with the interlayer insulating layer 115 therebetween, thereby forming a capacitance. The interlayer insulating layer 115 may serve as a dielectric layer of the storage capacitor Cst.

The second capacitor electrode CE2 of the storage capacitor Cst, the source electrode S1, and the drain electrode D1 may be covered with an inorganic protective layer PVX.

The inorganic protective layer PVX may be a single layer or multi-layer of silicon nitride (SiₓN_{y}) and/or silicon oxide (SiₓO_{y}). The inorganic protective layer PVX may be introduced to cover and protect some lines on the interlayer insulating layer 115.

A planarization layer 118 may be on the inorganic protective layer PVX. The planarization layer 118 may be formed as a single layer or a multi-layer, which is made of an organic material, and provide a flat top surface. The planarization layer 118 may include a general-purpose polymer such as benzocyclobutene (BCB), polyimide, hexamethyldisiloxane (HMDSO), polymethylmethacrylate (PMMA) and/or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, any suitable blend thereof, and/or the like.

A first contact hole CH1, a second contact hole CH2, and a third contact hole CH3, which penetrate the planarization layer 118, may be provided in the planarization layer 118. Each of the first contact hole CH1, the second contact hole CH2, and the third contact hole CH3 may electrically connect the light emitting element LD on the planarization layer 118 and the pixel circuit layer PCL to each other. The first contact hole CH1, the second contact hole CH2, and the third contact hole CH3 may include a conductive material (e.g., an electrically conductive material).

The first contact hole CH1 and the second contact hole CH2 may be spaced apart from each other at a (1-1)th distance D1_1. The second contact hole CH2 and the third contact hole CH3 may be spaced apart from each other at a (1-2)th distance D1_2. The (1-1)th distance D1_1 and the (1-2)th distance D1_2 may be the same. For example, the distance at which the first contact hole CH1 and the second contact hole CH2 are spaced apart from each other and the distance at which the second contact hole CH2 and the third contact hole CH3 are spaced apart from each other may be the same.

In the display area DA of the substrate SUB, the light emitting element LD may be on the planarization layer 118. The light emitting element LD may include a first light emitting element LD1 included in the first sub-pixel SPX1, a second light emitting element LD2 included in the second sub-pixel SPX2, and a third light emitting element LD3 included in the third sub-pixel SPX3. The first light emitting element LD1 may be electrically connected to the pixel circuit layer PCL through the first contact hole CH1, and the second light emitting element LD2 may be electrically connected to the pixel circuit layer PCL through the second contact hole CH2, and the third light emitting element LD3 may be electrically connected to the pixel circuit layer PCL through the third contact hole CH3. The light emitting element LD (each of the first to third light emitting elements LD1, LD2, and LD3) may include a first electrode 310, an intermediate layer 320 including a light emitting layer, and a second electrode 330.

The first electrode 310 may be a (semi-) transmissive electrode or a reflective electrode. In some embodiments, the first electrode 310 may include a reflective layer formed of Ag, Mg, Al, Pt, Pd, Au, Ni, Nd, Ir, Cr, any suitable compound thereof, and/or the like, and a transparent or translucent electrode layer on the reflective layer. The transparent or translucent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). In some embodiments, the first electrode 310 may be provided in a multi-layer structure of ITO/Ag/ITO. The first electrode 310 may be an anode electrode.

Hereinafter, a first electrode 310 included in the first light emitting element LD1 may be defined as a (1-1)th electrode 310_1, a first electrode 310 included in the second light emitting element LD2 may be defined as a (1-2)th electrode 310_2, and a first electrode 310 included in the third light emitting element LD3 may be defined as a (1-3)th electrode 310_3. Each of the (1-1)th electrode 310_1, the (1-2)th electrode 310_2, and the (1-3)th electrode 310_3 may be an anode electrode.

The (1-1)th electrode 310_1 and the (1-2)th electrode 310_2 may be spaced part from each other at a (2-1)th distance D2_1. The (1-2)th electrode 310_2 and the (1-3)th electrode 310_3 may be spaced apart from each other at a (2-2)th distance D2_2. The (2-1)th distance D2_1 and the (2-2)th distance D2_2 may be the same. For example, the distance at which the (1-2)th electrode 310_2 and the (1-3)th electrode 310_3 are spaced apart from each other and the distance at which the (1-2)th electrode 310_2 and the (1-3)th electrode 310_3 are spaced apart from each other may be the same.

A pixel defining layer 119 may be on the planarization layer 118. The pixel defining layer 119 may function to increase a distance between an edge of the first electrode 310 and the second electrode 330 above the first electrode 310, thereby preventing or reducing a likelihood or occurrence of an arc and/or the like at the edge of the first electrode 310. The pixel defining layer 119 may include an organic material and/or an inorganic material.

The intermediate layer 320 of the light emitting element LD may include an organic light emitting layer. The organic light emitting layer may include an organic material including a fluorescent and/or phosphorescent material that emits light of red, green, blue or white. The organic light emitting layer may be made of a low molecular weight organic material or a high molecular weight organic material, and functional layers such as a hole transport layer (HTL), a hole injection layer (HIL), an electron transport layer (ETL), and an electron injection layer (EIL) may be selectively further under/on the organic light emitting layer.

In the drawings, it is illustrated that the intermediate layer 320 is separately provided for each of the pixels SPX1, SPX2, and SPX3. However, the present disclosure is not limited thereto. The intermediate layer 320 may be integrally formed in each of the pixels SPX1, SPX2, and SPX3.

In this embodiment, the light emitting elements LD included in the pixels SPX1, SPX2, and SPX3 may all include organic light emitting layers emitting light of the same color. For example, the light emitting elements LD included in the pixels SPX1, SPX2, and SPX3 may all emit blue light.

The second electrode 330 may be a transmissive electrode or a reflective electrode. In some embodiments, the second electrode 330 may be a transparent or translucent electrode, and be formed of a metal thin film having a low work function, which includes Li, Ca, LiF/Ca, LiF/Al, Al, Ag, Mg, and/or any suitable compound thereof. In embodiments, a transparent conductive oxide (TCO) layer such as ITO, IZO, ZnO and/or In₂O₃ may further on the metal thin film. The second electrode 330 may be provided throughout the display area DA and the peripheral area PA, and be on the intermediate layer 320 and the pixel defining layer 119. The second electrode 330 may be integrally formed in a plurality of light emitting elements LD to correspond to a plurality of first electrodes 310. The second electrode 330 may be a cathode electrode.

A thin film encapsulation layer 400 may cover the light emitting element LD to protect the light emitting element LD from external moisture, oxygen and/or the like. The thin film encapsulation layer 400 may cover the display area DA, and extend to the outside of the display area DA. The thin film encapsulation layer 400 may include at least one organic encapsulation layer and at least one inorganic encapsulation layer. For example, the thin film encapsulation layer 400 may include a first inorganic encapsulation layer 410, an organic encapsulation layer 420, and a second inorganic encapsulation layer 430.

The first inorganic encapsulation layer 410 may cover the second electrode 330, and include an inorganic material such as silicon oxide, silicon nitride, and/or silicon trioxynitride. In some embodiments, other layers such as a capping layer may be between the first inorganic encapsulation layer 410 and the second electrode 330, if necessary or desired. Because the first inorganic encapsulation layer 410 is provided along a structure thereunder, a top surface of the first inorganic encapsulation layer 410 may not be flat. The organic encapsulation layer 420 may cover the first inorganic encapsulation layer 410, and a top surface of the organic encapsulation layer 420 may be approximately flat unlike the first inorganic encapsulation layer 410. In some embodiments, the top surface of the organic encapsulation layer 420 may be approximately flat at a portion corresponding to the display area DA. The organic encapsulation layer 420 may include an organic material including at least one material selected from the group consisting of polyethylene terephthalate, polyethylene naphthalate, polycarbonate, polyimide, polyethylene sulfonate, polyoxymethylene, polyarylate, and hexamethylsiloxane. The second inorganic encapsulation layer 430 may cover the organic encapsulation layer 420, and include an inorganic material such as silicon oxide, silicon nitride, and/or silicon trioxynitride.

The color filter unit CU may include an upper substrate 160, a first insulating layer 150 (e.g., a first electrically insulating layer 150), a second insulating layer 140 (e.g., a second electrically insulating layer 140), a light blocking layer 130, first to third filter layers 110R, 110G, and 110B, and a light conversion layer 120.

The upper substrate 160 may include a glass material, a ceramic material, a metal material, and/or a material having a flexible and/or bendable characteristics. If e.g., when) the upper substrate 160 has flexible and/or bendable characteristics, the upper substrate 160 may include a polymer resin such as polyethersulfone, polyacrylate, polyetherimide, polyethylene naphthalate, polyethylene terephthalate, polyphenylene sulfide, polyarylate, polyimide, polycarbonate, and/or cellulose acetate propionate. The upper substrate 160 may have a single-layer or multi-layer structure of the above-described material. When the upper substrate 160 has the multi-layer structure, the upper substrate 160 may further include an inorganic layer. In some embodiments, the upper substrate 160 may have a structure of organic material/inorganic material/organic material.

The light blocking layer 130 and the first to third filter layers 110R, 110G, and 110B may be on one surface of the upper substrate 160. The light blocking layer 130 and the first to third filter layers 110R, 110G, and 110B may be on the light conversion layer 120.

The light blocking layer 130 may be between the first to third filter layers 110R, 110G, and 110B to correspond to the non-emission layer NEA. The light blocking layer 130 may include a first filter opening 130_H1, a second filter opening 130_H2, and a third filter opening 130_H3, and the first to third filter layers 110R, 110G, and 110B may be provided in the first filter opening 130_H1, the second filter opening 130_H2, and the third filter opening 130_H3, respectively.

The first filter opening 130_H1, the second filter opening 130_H2, and the third filter opening 130_H3 may define an area (e.g., the emission area EA) in which light emitted from the light emitting element LD is output (e.g., emitted) to the outside of the display device DD. In some embodiments, the first filter opening 130_H1, the second filter opening 130_H2, and the third filter opening 130_H3 may have the same area in a plan view. For example, the first emission area EA1, the second emission area EA2, and the third emission area EA3 may have the same area in a plan view. However, the present disclosure is not limited thereto. In some embodiments, the first filter opening 130_H1, the second filter opening 130_H2, and the third filter opening 130_H3 may have different areas in a plan view. For example, the first emission area EA1, the second emission area EA2, and the third emission area EA3 may have different areas in a plan view. In some embodiments, in a plan view, two of the first filter opening 130_H1, the second filter opening 130_H2, and the third filter opening 130_H3 may have the same area, and the other of the first filter opening 130_H1, the second filter opening 130_H2, and the third filter opening 130_H3 may have an area different from the area of the two of the first filter opening 130_H1, the second filter opening 130_H2, and the third filter opening 130_H3. As such, the area of the first filter opening 130_H1, the second filter opening 130_H2, and the third filter opening 130_H3 in a plan view may be changed, and accordingly, the color coordinate of the display device can be adjusted.

The light blocking layer 130 is a black matrix, and may be a layer for improving color clarity and contrast. The light blocking layer 130 may include at least one selected from among a black pigment, a black dye, and a black particle. In some embodiments, the light blocking layer 130 may include a material such as Cr, CrO_{X}, Cr/CrO_{X}, Cr/CrO_{X}/CrN_{Y}, resin (e.g., carbon pigment and RGB mixed pigment), graphite, and/or a non-Cr based material.

The first to third filter layers 110R, 110G, and 110B may be (e.g., provide) a red color filter, a green color filter, and a blue color filter, respectively. Lights passing through the first to third filter layers 110R, 110G, and 110B have improved color reproducibilities of red, green, and blue, respectively.

The second insulating layer 140 may have first to third openings 141R, 141G, and 141B that expose the first to third filter layers 110R, 110G, and 110B. The second insulating layer 140 may include, for example, an organic material. However, the present disclosure is not limited thereto, and the second insulating layer 140 may include an inorganic material. In some cases, the second insulating layer 140 may include a light blocking material to serve as a light blocking layer. The light blocking material may include, for example, at least one selected from among a black pigment, a black dye, a black particle, and a metal particle.

First and second color conversion layer 120R and 120G and a transmission layer 120B may be provided in the first to third openings 141R, 141G, and 141B, respectively. The first color conversion layer 120R may be above the first light emitting element LD1. The first color conversion layer 120R may overlap with at least a portion of the first light emitting element LD1 in a plan view. The second color conversion layer 120G may be above the second light emitting element LD2. The second color conversion layer 120G may overlap with at least a portion of the second light emitting element LD2 in a plan view. The transmission layer 120B may be above the third light emitting element LD3. The transmission layer 120B may overlap with at least a portion of the third light emitting element LD3.

The first insulating layer 150 may be under the light conversion layer 120. The first insulating layer 150 may include, for example, an organic material. However, the present disclosure is not limited thereto. In some embodiments, the first insulating layer 150 may include an inorganic material.

In some embodiments, a spacer CS may be further under the first insulating layer 150. In some embodiments, the spacer CS may be under the light conversion layer 120 (the first color conversion layer 120R, the second color conversion layer 120G, and the transmission layer 120B). However, the present disclosure is not limited thereto. In some embodiments, the spacer CS may be on the light conversion layer 120.

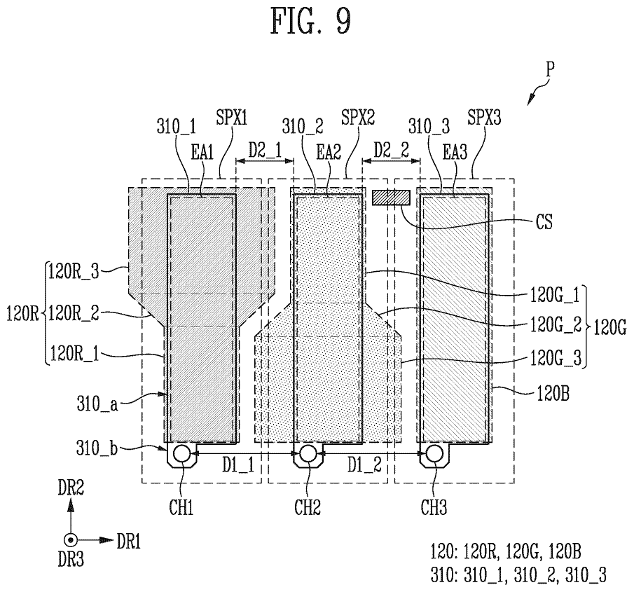

The spacer CS may be provided such that the substrate SUB and the upper substrate 160 maintain a set or certain distance. The spacer CS may be between the substrate SUB and the upper substrate 160. The spacer CS may not overlap with the light conversion layer 120 in a plan view. An example arrangement of the spacer CS will be further described with reference to FIG. 9.

In some embodiments, a filler 500 may be further between the substrate SUB and the upper substrate 160. For example, the filler 500 may be under the first insulating layer 150, and be on the thin film encapsulation layer 400. The filler 500 may perform a buffer action on external pressure and/or the like. The filler 500 may be made of an organic material such as methyl silicon, phenyl silicon, and/or polyimide. However, the present disclosure is not limited thereto, and the filler 500 may be made of urethane-based resin, epoxy-based resin and/or acryl-based resin, which is an organic sealant, silicon as an inorganic sealant, and/or the like.

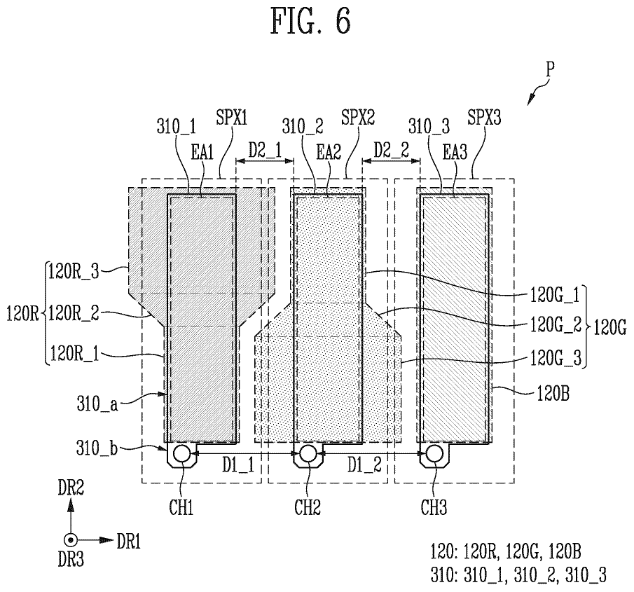

Hereinafter, the light conversion layer 120 and the first electrode 310 will be described in more detail with reference to FIG. 6. FIG. 6 is a schematic plan view of a pixel in accordance with a first embodiment of the present disclosure. FIG. 6 illustrates a plan view of the first electrode 310 and the light conversion layer 120. In FIG. 6, components except the first electrode 310 and the light conversion layer 120 are omitted.

Referring to FIG. 6, a (1-1)th electrode 310_1, a (1-2)th electrode 310_2, and a (1-3)th electrode 310_3 may have the same shape. The (1-1)th electrode 310_1, the (1-2)th electrode 310_2, and the (1-3)th electrode 310_3 may have the same area in a plan view.

Each of the (1-1)th electrode 310_1, the (1-2)th electrode 310_2, and the (1-3)th electrode 310_3 may include a first electrode portion 310_a and a second electrode portion 310_b. The first electrode portion 310_a may have a plate-shaped structure extending in the first direction DR1 and the second direction DR2. For example, the first electrode portion 310_a may have a rectangular planar shape having short sides that extend in the first direction DR1 and long sides that extend in the second direction DR2. However, the present disclosure is not limited thereto, and the first electrode portion 310_a may have various suitable shapes such as a quadrangular shape.

The second electrode portion 310_b may further extend in the opposite direction of the second direction DR2 from one of both sides (e.g., two sides) of the first electrode portion 310_a, which are opposite to each other. Both the sides of the first electrode portion 310_a, which are opposite to each other, may correspond to one end portion and the other portion of the first electrode portion 310_a in the first direction DR1. For example, the second electrode portion 310_b may further extend in the opposite direction of the second direction DR2 from an end portion provided at a left side selected from both the sides of the first electrode portion 310_a, which are opposite to each other. A width of the first electrode portion 310_a in the first direction DR1 may be greater than a width of the second electrode portion 310_b in the first direction DR1.

First electrode portions 310_a of a first sub-pixel SPX1 and a second sub-pixel SPX2 may be spaced apart from each other by a (2-1)th distance D2_1. First electrode portions 310_a of the second sub-pixel SPX2 and a third sub-pixel SPX3 may be spaced apart from each other by a (2-2)th distance D2_2. The (2-1)th distance D2_1 and the (2-2)th distance D2_2 may be the same.

Contact holes CH1, CH2, and CH3 may overlap with second electrode portions 310_b of the sub-pixels SPX1, SPX2, and SPX3. A first contact hole CH1 may overlap with a second electrode portion 310_b of the first sub-pixel SPX1 in a plan view. A second contact hole CH2 may overlap with a second electrode portion 310_b of the second sub-pixel SPX2 in a plan view. A third contact hole CH3 may overlap with a second electrode portion 310_b of the third sub-pixel SPX3 in a plan view.

The first contact hole CH1, the second contact hole CH2, and the third contact hole CH3 may have the same shape. For example, the first contact hole CH1, the second contact hole CH2, and the third contact hole CH3 may have the same shape in a plan view. The first contact hole CH1, the second contact hole CH2, and the third contact hole CH3 may have the same area in a plan view.

The first contact hole CH1 and the second contact hole CH2 may be spaced apart from each other by a (1-1)th distance D1_1. The second contact hole CH2 and the third contact hole CH3 may be spaced apart from each other by a (1-2)th distance D1_2. The (1-1)th distance D1_1 and the (1-2)th distance D1_2 may be the same.

In the display device DD in accordance with embodiments of the present disclosure, the first electrodes 310_1, 310_2, and 310_3 of the sub-pixels SPX1, SPX2, and SPX3 may have the same shape, the contact holes CH1, CH2, and CH3 of the sub-pixels SPX1, SPX2, and SPX3 may have the same shape, adjacent first electrodes 310_1, 310_2, and 310_3 may be spaced apart from each other by the same distance, and adjacent contact holes CH1, CH2, and CH3 may be spaced apart from each other at the same distance. Accordingly, a process of manufacturing the first electrode 310 is simplified, so that manufacturing processes of the display device DD can be simplified and manufacturing cost can be reduced.

A first color conversion layer 120R may include a (1-1)th portion 120R_1, a (1-2)th portion 120R_2, and a (1-3)th portion 120R_3. The first color conversion layer 120R may have a shape that is symmetrical with respect to the second direction DR2. Hereinafter, the term “symmetrical in one direction” and variations thereof mean being symmetrical with respect to a line that extends in the one direction.

The (1-1)th portion 120R_1 may have a rectangular planar shape having short sides that extend in the first direction DR1 and long sides that extend in the second direction DR2. The (1-1)th portion 120R_1 may have a shape that is symmetrical with respect to the second direction DR2. However, the present disclosure is not limited thereto, and the (1-1)th portion 120R_1 may have a quadrangular shape or another polygonal shape, which is symmetrical with respect to the second direction DR2, in addition to the rectangular shape.

The (1-2)th portion 120R_2 may extend from the (1-1)th portion 120R_1 in the same direction (e.g., the second direction DR2) as the direction in which the (1-1)th portion 120R_1 extends, and a width of the (1-2)th portion 120R_2 in a direction (e.g., the first direction DR1) perpendicular (e.g., substantially perpendicular) to the second direction DR2 may be widened. The (1-2)th portion 120R_2 may have a width gradually widened in the second direction DR2. For example, the (1-2)th portion 120R_2 may extend to have a width widened in the first direction DR1 from the (1-1)th portion 120R_1. For example, a width of the (1-2)th portion 120R_2 in at least one area may be different from a width of the (1-1)th portion 120R_1.

The (1-2)th portion 120R_2 may have a shape that is symmetrical with respect to the second direction DR2. For example, the (1-2)th portion 120R_2 may have a trapezoidal shape that is symmetrical with respect to the second direction DR2.

At least a portion of the (1-2)th portion 120R_2 may not overlap with the (1-1)th electrode 310_1 in a plan view. At least a portion of the (1-2)th portion 120R_2 may not overlap with a first emission area EA1 in a plan view. Portions of the (1-2)th portion 120R_2, which do not overlap with the first emission area EA1, may be provided at both sides (e.g., left and right sides) of the first emission area EA1 in a plan view. The portions of the (1-2)th portion 120R_2, which do not overlap with the first emission area EA1, may be symmetrical to each other with respect to the second direction DR2.

The (1-3)th portion 120R_3 may extend from the (1-2)th portion 120R_2 in the same direction (e.g., the second direction DR2) as the direction in which the (1-2)th portion 120R_2 extends, and have a constant width. For example, the (1-3)th portion 120R_3 may have the same width as the widest width among widths of the (1-2)th portion 120R_2 in the first direction DR1.

The (1-3)th portion 120R_3 may have a shape that is symmetrical with respect to the second direction DR2. For example, the (1-3)th portion 120R_3 may have a quadrangular shape that is symmetrical with respect to the second direction DR2.

At least a portion of the (1-3)th portion 120R_3 may not overlap with the (1-1)th electrode 310_1 in a plan view. At least a portion of the (1-3)th portion 120R_3 may not overlap with the first emission area EA1 in a plan view. Portions of the (1-3)th portion 120R_3, which do not overlap with the first emission area EA1, may be provided at both sides (e.g., left and right sides) of the first emission area EA1 in a plan view. The portions of the (1-3)th portion 120R_3, which do not overlap with the first emission area EA1, may be symmetrical to each other with respect to the second direction DR2.

The first color conversion layer 120R in accordance with embodiments of the present disclosure includes at least a portion that does not overlap with the first emission area EA1, so that a margin area to provide the first color conversion layer 120R can be secured or provided. The first color conversion layer 120R may be formed as an ink is discharged through an inkjet printing apparatus. The first color conversion layer 120R includes at least a portion that does not overlap with the first emission area EA1, so that a margin area to which the ink can be discharged can be secured or provided. If (e.g., when) the margin area to which the ink can be discharge is not secured or provided, it may be difficult for the first color conversion layer 120R to be formed in an area corresponding to the first emission area EA1. In the display device DD in accordance with embodiments of the present disclosure, a margin area can be secured or provided in an inkjet process of forming the first color conversion layer 120R, and the first color conversion layer 120R can be formed in the area corresponding to the first emission area EA1.

A second color conversion layer 120G may include a (2-1)th portion 120G_1, a (2-2)th portion 120G_2, and a (2-3)th portion 120G_3. The second color conversion layer 120G may have a shape that is symmetrical with respect to the second direction DR2. The second color conversion layer 120G may have a shape that is point-symmetrical to the shape of the first color conversion layer 120R. For example, the second color conversion layer 120G and the first color conversion layer 120G may be point-symmetrical to each other with respect to a reference point located at the center on the second color conversion layer 120G. Hereinafter, a first figure and a second figure being “point-symmetrical to each other” means that the first figure and the second figure are in a point-symmetrical relationship with respect to a reference point located at the center of the first figure.

The (2-1)th portion 120G_1 may have a rectangular planar shape having short sides that extend in the first direction DR1 and long sides that extend in the second direction DR2. The (2-1)th portion 120G_1 may have a shape that is symmetrical with respect to the second direction DR2. However, the present disclosure is not limited thereto, and the (2-1)th portion 120G_1 may have a quadrangular shape or another polygonal shape, which is symmetrical with respect to the second direction DR2, in addition to or alternatively to the rectangular shape. The (2-1)th portion 120G_1 may have the same shape and area as the (1-1)th portion 120R_1 in a plan view. The (2-1)th portion 120G_1 may be point-symmetrical to the (1-1)th portion 120R_1.

The (2-2)th portion 120G_2 may extend in the same direction (e.g., the opposite direction of the second direction DR2) as the direction in which the (2-1)th portion 120G_1 extends, and a width of the (2-2)th portion 120G_2 in a direction (e.g., the first direction DR1) perpendicular (e.g., substantially perpendicular) to the second direction DR2 may be widened. For example, the (2-2)th portion 120G_2 may extend to have a width widened in the first direction DR1 from the (2-1)th portion 120G_1. For example, a width of the (2-2)th portion 120G_2 in at least one area may be different from a width of the (2-1)th portion 120G_1.

The (2-2)th portion 120G_2 may have a shape that is symmetrical with respect to the second direction DR2. For example, the (2-2)th portion 120G_2 may have a trapezoidal shape that is symmetrical with respect to the second direction DR2.

At least a portion of the (2-2)th portion 120G_2 may not overlap with the (1-2)th electrode 310_2 in a plan view. At least a portion of the (2-2)th portion 120G_2 may not overlap with a second emission area EA2 in a plan view. Portions of the (2-2)th portion 120G_2, which do not overlap with the second emission area EA2, may be provided at both sides (e.g., left and right sides) of the second emission area EA2 in a plan view. The portions of the (2-2)th portion 120G_2, which do not overlap with the second emission area EA2, may be symmetrical to each other with respect to the second direction DR2. The (2-2)th portion 120G may have a shape point-symmetrical to the shape of the (1-2)th portion 120R_2 when viewed in a plan view, and have the same area as the (1-2)th portion 120R_2.

The (2-3)th portion 120G_3 may extend in the same direction (e.g., the opposite direction of the second direction DR2) as the direction in which the (2-2)th portion 120G_2 extends, and have a constant width. For example, the (2-3)th portion 120G_3 may have the same width as the widest width among widths of the (2-2)th portion 120G_2 in the first direction DR1. The (2-3)th portion 120G_3 may have a shape that is symmetrical with respect to the second direction DR2. The (2-3)th portion 120G_3 may have the same shape and area as the (1-3)th portion 120R_3 in a plan view. The (2-3)th portion 120G_3 may be point-symmetrical to the (1-3)th portion 120R_3.

At least a portion of the (2-3)th portion 120G_3 may not overlap with the (1-2)th electrode 310_2 in a plan view. At least a portion of the (2-3)th portion 120G_3 may not overlap with the second emission area EA2 in a plan view. Portions of the (2-3)th portion 120G_3, which do not overlap with the second emission area EA2, may be provided at both sides (e.g., left and right sides) of the first emission area EA1 in a plan view. The portions of the (2-3)th portion 120G_3, which do not overlap with the second emission area EA2, may be symmetrical to each other with respect to the second direction DR2.

The display device DD in accordance with embodiments of the present disclosure has a pixel P structure in which the first color conversion layer 120R includes a portion that does not overlap with the first emission area EA1, the second color conversion layer 120G includes a portion that does not overlap with the second emission area EA2, and the portion at which the first color conversion layer 120R does not overlap with the first emission area EA1 and the portion at which the second color conversion layer 120G does not overlap with the second emission area EA2 have shapes that are point-symmetrical to each other.

The second color conversion layer 120G in accordance with embodiments of the present disclosure includes at least a portion that does not overlap with the second emission area EA2, so that a margin area to form the second color conversion layer 120G can be secured or provided. The second color conversion layer 120G may be formed as the ink is discharged through the inkjet printing apparatus. The second color conversion layer 120G includes at least a portion that does not overlap with the second emission area EA2, so that a margin area to which the ink can be discharged can be secured or provided.

A transmission area 120B may have a rectangular planar shape having short sides that extend in the first direction DR1 and long sides that extend in the second direction DR2. The transmission layer 120B may have a shape that is symmetrical with respect to each of the second direction DR2 and the first direction DR1. However, the present disclosure is not limited thereto, and the transmission layer 120B may have a quadrangular shape or another polygonal shape, which is symmetrical with respect to each of the second direction DR2 and the first direction DR1, in addition to or alternatively to the rectangular shape.

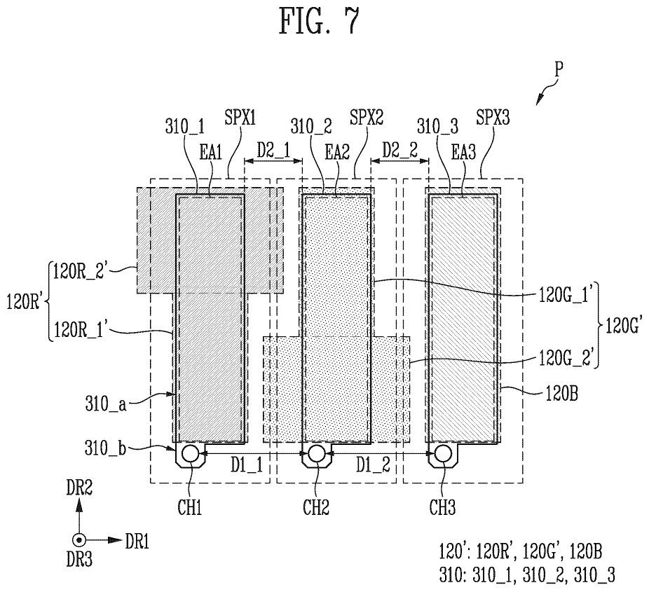

Hereinafter, a display device in accordance with a second embodiment of the present disclosure will be described. FIG. 7 is a schematic plan view of a pixel in accordance with a second embodiment of the present disclosure. FIG. 7 illustrates a plan view of a first electrode 310 and a light conversion layer 120′. Duplicative description of components described herein above, except the first electrode 310 and the light conversion layer 120′, is not repeated with respect to FIG. 7.

The second embodiment has a structure of the light conversion layer 120′ different from the light conversion layer 120 in accordance with the first embodiment of the present disclosure. Hereinafter, descriptions of portions overlapping with the above-described portion will not be repeated.

A first color conversion layer 120R′ may include a (1-1)th portion 120R_1′ and a (1-2)th portion 120R_2′. The first color conversion layer 120R′ may have a shape that is symmetrical with respect to the second direction DR2.

The (1-1)th portion 120R_1′ may have a rectangular planar shape having short sides that extend in the first direction DR1 and long sides that extend in the second direction DR2. The (1-1)th portion 120R_1′ may have a shape that is symmetrical with respect to the second direction DR2. However, the present disclosure is not limited thereto, and the (1-1)th portion 120R_1′ may have a quadrangular shape or another polygonal shape, which is symmetrical with respect to the second direction DR2, in addition to or alternatively to the rectangular shape.

The (1-2)th portion 120R_2′ may extend in the same direction (e.g., the second direction DR2) as the direction in which the (1-1)th portion 120R_1′ extends. The (1-2)th portion 120R_2′ may have a width wider in the first direction DR1 than a width of the (1-1)th portion 120R_1′. Each of the (1-2)th portion 120R_2′ and the (1-1)th portion 120R_1′ may have a constant width. The (1-2)th portion 120R_2′ may have a shape that is symmetrical with respect to the second direction DR2.

At least a portion of the (1-2)th portion 120R_2′ may not overlap with a (1-1)th electrode 310_1 in a plan view. At least a portion of the (1-2)th portion 120R_2′ may not overlap with a first emission area EA1 in a plan view. Portions of the (1-2)th portion 120R_2′, which do not overlap with the first emission area EA1, may be provided at both sides (e.g., left and right sides) of the first emission area EA1 in a plan view. The portions of the (1-2)th portion 120R_2′, which do not overlap with the first emission area EA1, may be symmetrical to each other with respect to the second direction DR2.

A second color conversion layer 120G′ may include a (2-1)th portion 120G_1′ and a (2-2)th portion 120G_2′. The second color conversion layer 120G′ may have a shape that is symmetrical with the second direction DR2. The second color conversion layer 120G′ may have a shape that is point-symmetrical to the shape of the first color conversion layer 120R′. The second color conversion layer 120G′ and the first color conversion layer 120R′ may be point-symmetrical to each other.

The (2-1)th portion 120G_1′ may have a rectangular planar shape having short sides that extend in the first direction DR1 and long sides that extend in the second direction DR2. The (2-1)th portion 120G_1′ may have a shape that is symmetrical with respect to the second direction DR2. However, the present disclosure is not limited thereto, and the (2-1)th portion 120G_1′ may have a quadrangular shape or another polygonal shape, which is symmetrical with respect to the second direction DR2, in addition to or alternatively to the rectangular shape. The (2-1)th portion 120G_1′ may have the same shape and area as the (1-1)th portion 120R_1′ in a plan view. The (2-1)th portion 120G_1′ may be point-symmetrical to the (1-1)th portion 120R_1′.

The (2-2)th portion 120G_2′ may extend in the same direction (e.g., the opposite direction of the second direction DR2) as the direction in which the (2-1)th portion 120G_1′ extends. The (2-2)th portion 120G_2′ may have a width wider in the first direction DR1 than a width of the (2-1)th portion 120G_1′. Each of the (2-2)th portion 120G_2′ and the (2-1)th portion 120G_1′ may have a constant width.

The (2-2)th portion 120G_2′ may have a shape that is symmetrical with respect to the second direction DR2. The (2-2)th portion 120G_2′ may have the same shape and area as the (1-2)th portion 120R_2′ in a plan view. The (2-2)th portion 120G_2′ and the (1-2)th portion 120R_2′ may be point-symmetrical to each other.

At least a portion of the (2-2)th portion 120G_2′ may not overlap with a (1-2)th electrode 310_2 in a plan view. At least a portion of the (2-2)th portion 120G_2′ may not overlap with a second emission area EA2 in a plan view. Portions of the (2-2)th portion 120G_2′, which do not overlap with the second emission area EA2, may be provided at both sides (e.g., left and right sides) of the second emission area EA2 in a plan view. The portions of the (2-2)th portion 120G_2′, which do not overlap with the second emission area EA2, may be symmetrical to each other with respect to the second direction DR2.

In the display device DD in accordance with the second embodiment of the present disclosure, the first color conversion layer 120R′ includes a portion that does not overlap with the first emission area EA1, and the second color conversion layer 120G′ includes a portion that does not overlap with the second emission area EA2, so that a margin area to which the ink can be discharged can be secured or provided.

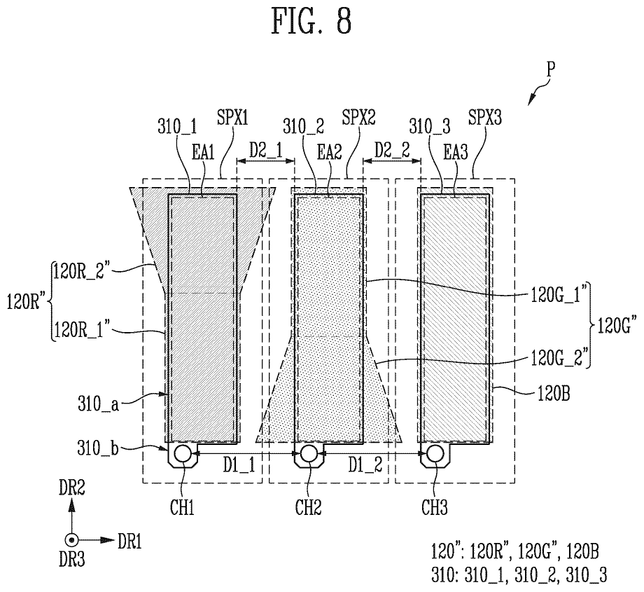

Hereinafter, a display device in accordance with a third embodiment of the present disclosure will be described. FIG. 8 is a schematic plan view of a pixel in accordance with a third embodiment of the present disclosure. FIG. 8 illustrates a plan view of a first electrode 310 and a light conversion layer 120″. Duplicative description of components described herein above, except the first electrode 310 and the light conversion layer 120″, will not be repeated with respect to FIG. 8.

The third embodiment has a structure of the light conversion layer 120″ different from the light conversion layer 120 in accordance with the first embodiment of the present disclosure. Hereinafter, descriptions of portions overlapping with the above-described portion will not be repeated.

A first color conversion layer 120R″ may include a (1-1)th portion 120R_1″ and a (1-2)th portion 120R_2″. The first color conversion layer 120R″ may have a shape that is symmetrical with respect to the second direction DR2.

The (1-1)th portion 120R_1″ may correspond to the above-described (1-1)th portion 120R_1′ of the second embodiment.

The (1-2)th portion 120R_2″ may extend in the same direction (e.g., the second direction DR2) as the direction in which the (1-1)th portion 120R_1″ extends. The (1-2)th portion 120R_2′ may have a width in the first direction DR1, which is widened in the second direction DR2. For example, the (1-2)th portion 120R_2″ may have a width in the first direction DR1, which is widened as becoming distant from the (1-1)th portion 120R_1″. The (1-2)th portion 120R_2″ may have a trapezoidal shape that is symmetrical with respect to the second direction DR2.

At least a portion of the (1-2)th portion 120R_2″ may not overlap with a (1-1)th electrode 310_1 in a plan view. At least a portion of the (1-2)th portion 120R_2″ may not overlap with a first emission area EA1 in a plan view. Portions of the (1-2)th portion 120R_2″, which do not overlap with the first emission area EA1, may be provided at both sides (e.g., left and right sides) of the first emission area EA1 in a plan view. The portions of the (1-2)th portion 120R_2″, which do not overlap with the first emission area EA1, may be symmetrical to each other with respect to the second direction DR2.

A second color conversion layer 120G″ may include a (2-1)th portion 120G_1″ and a (2-2)th portion 120G_2″. The second color conversion layer 120G″ may have a shape that is symmetrical with the second direction DR2. The second color conversion layer 120G″ may have a shape that is point-symmetrical to the shape of the first color conversion layer 120R″. The second color conversion layer 120G″ may be point-symmetrical to the first color conversion layer 120R″.

The (2-1)th portion 120G_1″ may correspond to the above-described (2-1)th portion 120G_1′ of the second embodiment.

The (2-2)th portion 120G_2″ may extend in the same direction (e.g., the opposite direction of the second direction DR2) as the direction in which the (2-1)th portion 120G_1″ extends. The (2-2)th portion 120G_2″ may have a width in the first direction DR1, which is widened in the second direction DR2. For example, the (2-2)th portion 120G_2″ may have a width in the first direction DR1, which is widened as becoming distant from the (2-1)th portion 120G_1″. The (2-2)th portion 120G_2″ may have a trapezoidal shape that is symmetrical with respect to the second direction DR2. The (2-2)th portion 120G_2″ may have a shape that is point-symmetrical to the shape of the (1-2)th portion 120R_2″ in a plan view, and have the same area as the (1-2)th portion 120R_2″. The (2-2)th portion 120G_2″ may be point-symmetrical to the (1-2)th portion 120R_2″.

At least a portion of the (2-2)th portion 120G_2″ may not overlap with a (1-2)th electrode 310_2 in a plan view. At least a portion of the (2-2)th portion 120G_2″ may not overlap with a second emission area EA2 in a plan view. Portions of the (2-2)th portion 120G_2″, which do not overlap with the second emission area EA2, may be provided at both sides (e.g., left and right sides) of the second emission area EA2 in a plan view. The portions of the (2-2)th portion 120G_2″, which do not overlap with the second emission area EA2, may be symmetrical to each other with respect to the second direction DR2.

In the display device DD in accordance with the third embodiment of the present disclosure, the first color conversion layer 120R″ includes a portion that does not overlap with the first emission area EA1, and the second color conversion layer 120G″ includes a portion that does not overlap with the second emission area EA2, so that a margin area to which the ink can be discharged can be secured or provided.

In the display device DD in accordance with embodiments of the present disclosure, in a plan view, portions of the first color conversion layer 120R, 120R′ and/or 120R″, which do not overlap with the first emission area EA1, are provided at both sides of the first emission area EA1, and portions of the second color conversion layer 120G, 120G′ and/or 120G″, which do not overlap with the second emission area EA2, are provided at both sides of the second emission area EA2, so that the first electrode 310_1, 310_2, and 310_3 can have the same shape and area and be spaced apart from each other at the same distance.

Hereinafter, an arrangement of the spacer CS will be described with reference to FIG. 9. FIG. 9 is a plan view schematically illustrating an arrangement of the spacer in accordance with an embodiment of the present disclosure.

Referring to FIG. 9, the spacer CS may be between the second color conversion layer 120G and the transmission layer 120B in a plan view. For example, the spacer CS may be between the (2-1)th portion 120G_1 of the second color conversion layer 120G and the transmission layer 120B in a plan view.

In the display device DD in accordance with embodiments of the present disclosure, the (2-1)th portion 120G_1 of the second color conversion layer 120G may have a width narrower in the first direction DR1 than a width of the (2-3)th portion 120G_3 of the second color conversion layer 120G, and a space in which the spacer CS is provided may be between the (2-1)th portion 120G_1 and the transmission layer 120B. Accordingly, the spacer CS may be between the (2-1)th portion 120G_1 and the transmission layer 120B, so that a distance between the substrate SUB and the upper substrate 160 can be maintained.

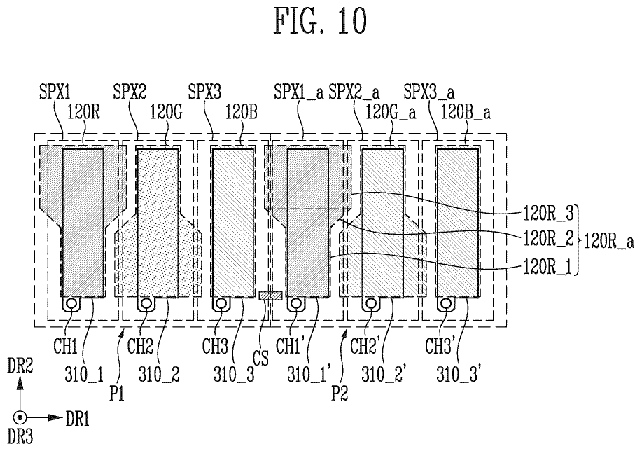

Hereinafter, an arrangement of the spacer CS will be described with reference to FIG. 10. FIG. 10 is a plan view schematically illustrating an arrangement of the spacer in accordance with another embodiment of the present disclosure.

Hereinafter, in FIG. 10, for convenience of description, first to third sub-pixels SPX1, SPX2, and SPX3 of the second pixel P2 may be defined as a first adjacent sub-pixel SPX1_a, a second adjacent sub-pixel SPX2_a, and a third adjacent sub-pixel SPX3_a, respectively. In some embodiments, a first color conversion layer 120R, a second color conversion layer 120G, and a transmission layer 120B of the second pixel P2 may be defined as a first adjacent color conversion layer 120R_a, a second adjacent color conversion layer 120G_a, and an adjacent transmission layer 120B_a, respectively.

In some embodiments, a (1-1)th electrode 310_1, a (1-2)th electrode 310_2, and a (1-3)th electrode 310_3 of the second pixel P2 may be defined as a (1-1)th adjacent electrode 310_1′, a (1-2)th adjacent electrode 310_2′, and a (1-3)th adjacent electrode 310_3′, respectively, and first to third contact holes CH1, CH2, and CH3 of the second pixel P2 may be defined as first to third adjacent contact holes CH1′, CH2′, and CH3′, respectively.

The second pixel P2 may include the first adjacent sub-pixel SPX1_a, the second adjacent sub-pixel SPX2_a, and the third adjacent sub-pixel SPX3_a, and the first to third adjacent sub-pixels SPX1_a, SPX2_a, and SPX3_a may have the same structures as the above-described first to third sub-pixels SPX, SPX2, and SPX3, respectively. The first adjacent color conversion layer 120R_a, the second adjacent color conversion layer 120G_a, and the adjacent transmission layer 120B_a may have the same structures as the first color conversion layer 120R, the second color conversion layer 120G, and the transmission layer 120B, which are described above, respectively. The (1-1)th adjacent electrode 310_1′, the (1-2)th adjacent electrode 310_2′, and the (1-3)th adjacent electrode 310_3′ may have the same structure as the (1-1)th electrode 310_1, the (1-2)th electrode 310_2, and the (1-3)th electrode 310_3. The first to third adjacent contact holes CH1, CH2, and CH3 may have the same structure as the first to third contact holes CH1, CH2, and CH3.

The (1-1)th adjacent electrode 310_1′, the (1-2)th adjacent electrode 310_2′, and the (1-3)th adjacent electrode 310_3′ may be spaced apart from each other by the same distance. The (1-1)th adjacent electrode 310_1′, the (1-2)th adjacent electrode 310_2′, and the (1-3)th adjacent electrode 310_3′ may be disposed to be spaced apart from each other by the distance at which the (1-1)th electrode 310_1, the (1-2)th electrode 310_2, and the (1-3)th electrode 310_3 are spaced apart from each other. The (1-1)th adjacent electrode 310_1′ and the (1-2)th adjacent electrode 310_2′ may be spaced apart from each other by the (2-1)th distance D2_1 or the (2-2)th distance D2_2. The (1-2)th adjacent electrode 310_2′ and the (1-3)th adjacent electrode 310_3′ may be spaced apart from each other by the (2-1)th distance D2_1 or the (2-2)th distance D2_2.

Adjacent sub-pixels between the first pixel P1 and the second pixel P2 may be spaced apart from each other by the same distance. For example, the (1-1)th adjacent electrode 310_1′ and the (1-3)th electrode 310_3 may be spaced apart from each other by the same distance.

The first adjacent contact hole CH1′, the second adjacent contact hole CH2′, and the third adjacent contact hole CH3′ may be spaced apart from each other by the same distance. The first adjacent contact hole CH1′, the second adjacent contact hole CH2′, and the third adjacent contact hole CH3′ may be spaced apart from each other by the distance at which the first contact hole CH1, the second contact hole CH2, and the third contact hole CH3 are spaced apart from each other. The first adjacent contact hole CH1′ and the second adjacent contact hole CH2′ may be spaced apart from each other by the (1-1)th distance D1_1 or the (1-2)th distance D1_2. The second adjacent contact hole CH2′ and the third adjacent contact hole CH3′ may be spaced apart from each other by the (1-1)th distance D1_1 or the (1-2)th distance D1_2.

Referring to FIG. 10, the spacer CS may be between the transmission layer 120B and the first adjacent color conversion layer 120R_a in a plan view. For example, the spacer CS may be between a (1-1)th portion 120R_1 of the first adjacent color conversion layer 120R_a and the transmission layer 120B in a plan view.

In the display device DD in accordance with embodiments of the present disclosure, the (1-1)th portion 120R_1 of the first adjacent color conversion layer 120R_a may have a width narrower in the first direction DR1 than a (1-3)th portion of the first adjacent color conversion layer 120R_a, and a space in which the spacer CS is provided may be between the (1-1)th portion 120R_1 of the first adjacent color conversion layer 120R_a and the transmission layer 120B. The spacer CS may be between the (1-1)th portion 120R_1 of the first adjacent color conversion layer 120R_a and the transmission layer 120B, so that the distance between the substrate SUB and the upper substrate 160 can be maintained.

A display device according to an embodiment is applicable to various types of electronic devices. In an embodiment, an electronic device includes the above-described display device and may further include other modules or devices having additional functions in addition to the display device.

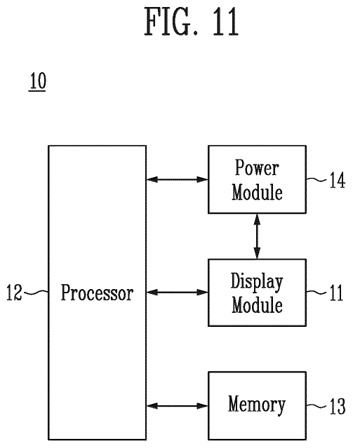

FIG. 11 is a block diagram of an electronic device according to an embodiment. Referring to FIG. 11, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

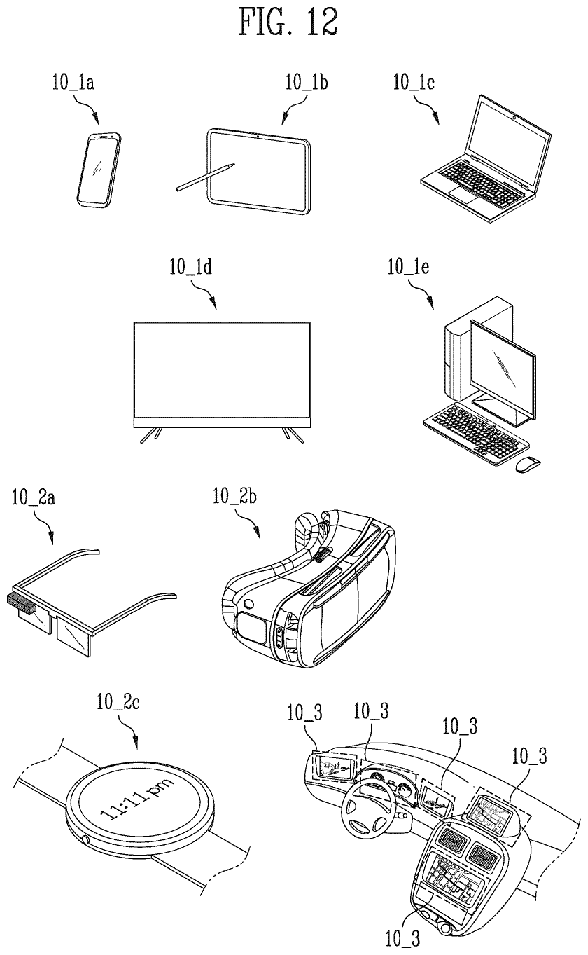

FIG. 12 shows schematic views of various embodiments of an electronic device.

Referring to FIG. 12, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

In accordance with embodiments of the present disclosure, there can be provided a display device capable of simplifying manufacturing processes of the display device and securing or providing a margin area to form light conversion layers including a quantum dot.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various suitable changes in form and details may be made without departing from the spirit and scope of the present disclosure as set forth in the following claims, and equivalents thereof.

What is claimed is:

1. A display device comprising:
a display area comprising a first pixel comprising a first sub-pixel, a second sub-pixel, and a third sub-pixel;
a first light emitting element included in the first sub-pixel;
a second light emitting element included in the second sub-pixel; and
a third light emitting element included in the third sub-pixel,
wherein the first light emitting element comprises a (1-1)th electrode,
the second light emitting element comprises a (1-2)th electrode, and
the third light emitting element comprises a (1-3)th electrode, and
wherein the (1-1)th electrode is spaced apart from the (1-2)th electrode at a (2-1)th distance, and
the (1-2)th electrode is spaced apart from the (1-3)th electrode at a (2-2)th distance equal to the (2-1)th distance.

2. The display device of claim 1, wherein each of the (1-1)th electrode, the (1-2)th electrode, and the (1-3)th electrode is an anode electrode, and
wherein the (1-1)th electrode, the (1-2)th electrode, and the (1-3)th electrode have the same shape.

3. The display device of claim 1, wherein the (1-1)th electrode, the (1-2)th electrode, and the (1-3)th electrode have same area in a plan view.

4. The display device of claim 1, further comprising a light conversion layer comprising:
a first color conversion layer above the first light emitting element;
a second color conversion layer above the second light emitting element; and
a transmission layer above the third light emitting element,
wherein the first color conversion layer and the second color conversion layer have respective shapes that are point-symmetrical to each other.

5. The display device of claim 4, wherein the first color conversion layer comprises:
a (1-1)th portion that extends in a first direction and a second direction;
a (1-2)th portion that extends in the second direction from the (1-1)th portion; and
a (1-3)th portion that extends in the second direction from the (1-2)th portion,
wherein the (1-2)th portion has a width widened in the second direction, and
wherein each of the first color conversion layer and the second color conversion layer has a shape that is symmetrical with respect to a line that extends in the second direction in a plan view.

6. The display device of claim 4, wherein the first color conversion layer comprises:
a (1-1)th portion that extends in a first direction and a second direction; and
a (1-2)th portion that extends in the second direction from the (1-1)th portion,
wherein the (1-2)th portion has a width which is wider than a width of the (1-1)th portion and is constant, or has a width widened in the second direction, and
wherein each of the first color conversion layer and the second color conversion layer has a shape that is symmetrical with respect to a line that extends in the second direction in a plan view.

7. The display device of claim 1, further comprising:
a pixel circuit layer comprising a pixel circuit;
a first contact hole that electrically connects the first light emitting element and the pixel circuit layer to each other;
a second contact hole that electrically connects the second light emitting element and the pixel circuit layer to each other; and
a third contact hole that electrically connects the third light emitting element and the pixel circuit layer to each other,
wherein the first contact hole and the second contact hole are spaced apart from each other at a (1-1)th distance, and
the second contact hole and the third contact hole are spaced apart from each other at a (1-2)th distance equal to the (1-1)th distance.

8. The display device of claim 4, further comprising a spacer under the light conversion layer,
wherein the spacer is between the second color conversion layer and the transmission layer in a plan view.

9. The display device of claim 4, further comprising:
a second pixel arranged with the first pixel in the first direction, the second pixel comprising a first adjacent sub-pixel, a second adjacent sub-pixel, and a third adjacent sub-pixel; and
a spacer under the light conversion layer,
wherein the second pixel comprising a first adjacent color conversion layer having the same structure as the first color conversion layer, and
wherein the spacer is between the transmission layer and the first adjacent color conversion layer in a plan view.

10. The display device of claim 4, further comprising a light blocking layer on the light conversion layer,
wherein the light blocking layer comprises:
a first filter opening that defines a first emission area;
a second filter opening that defines a second emission area; and
a third filter opening that defines a third emission area, and
wherein the first emission area, the second emission area, and the third emission area have different respective areas in a plan view.

11. A display device comprising:
a display area comprising a first pixel including a first sub-pixel, a second sub-pixel, and a third sub-pixel;
a first light emitting element included in the first sub-pixel;
a second light emitting element included in the second sub-pixel;
a third light emitting element included in the third sub-pixel; and
a light conversion layer above the first to third light emitting elements,
wherein the light conversion layer comprises a first color conversion layer, a second color conversion layer, and a transmission layer,
wherein the first color conversion layer and the second color conversion layer have shapes that are point-symmetrical to each other in a plan view, and
wherein each of the first color conversion layer and the second color conversion layer has a shape that is symmetrical with respect to a line that extends in one direction in a plan view.

12. The display device of claim 11, wherein the first light emitting element comprises a (1-1)th electrode,
the second light emitting element comprises a (1-2)th electrode, and
the third light emitting element comprises a (1-3)th electrode,
wherein the (1-1)th electrode is spaced apart from the (1-2)th electrode at a (2-1)th distance, and
the (1-2)th electrode is spaced apart from the (1-3)th electrode at a (2-2)th distance equal to the (2-1)th distance, and
wherein each of the (1-1)th electrode, the (1-2)th electrode, and the (1-3)th electrode is an anode electrode.

13. The display device of claim 11, further comprising:
a pixel circuit layer comprising a pixel circuit;
a first contact hole that electrically connects the first light emitting element and the pixel circuit layer to each other;
a second contact hole that electrically connects the second light emitting element and the pixel circuit layer to each other; and
a third contact hole that electrically connects the third light emitting element and the pixel circuit layer to each other,
wherein the first contact hole and the second contact hole are spaced apart from each other at a (1-1)th distance, and
the second contact hole and the third contact hole are spaced apart from each other at a (1-2)th distance equal to the (1-1)th distance.

14. The display device of claim 11, wherein the first color conversion layer comprises:
a (1-1)th portion having a short side in a direction perpendicular to the one direction and a long side in the one direction;
a (1-2)th portion having a trapezoidal shape having a width widened in the one direction; and
a (1-3)th portion that extends in the one direction from the (1-2)th portion.

15. The display device of claim 11, wherein the first color conversion layer comprises:
a (1-1)th portion having a short side in a direction perpendicular to the one direction and a long side in the one direction; and
a (1-2)th portion that extends in the one direction from the (1-1)th portion, and
wherein the (1-2)th portion has a width which is wider than a width of the (1-1)th portion and is constant, or has a width widened in the one direction.

16. The display device of claim 14, further comprising a light blocking layer on the light conversion layer,
wherein the light blocking layer comprises:
a first filter opening that defines a first emission area;
a second filter opening that defines a second emission area; and
a third filter opening that defines a third emission area, and
wherein at least a portion of the (1-2)th portion and at least a portion of the (1-3)th portion do not overlap with the first emission area in a plan view, and
wherein the first filter opening, the second filter opening, and the third filter opening have different respective areas in a plan view.

17. The display device of claim 16, wherein the at least a portion of the (1-2)th portion and the at least a portion of the (1-3)th portion are provided at both sides of the first emission area in a plan view.

18. The display device of claim 11, further comprising a spacer under the light conversion layer,
wherein the spacer is between the second color conversion layer and the transmission layer in a plan view.

19. The display device of claim 11, further comprising:
a second pixel arranged with the first pixel in the one direction, the second pixel including a first adjacent sub-pixel, a second adjacent sub-pixel, and a third adjacent sub-pixel; and
a spacer under the light conversion layer,
wherein the second pixel comprises a first adjacent color conversion layer having the same structure as the first color conversion layer, and
wherein the spacer is between the transmission layer and the first adjacent color conversion layer in a plan view.

20. An electronic device, comprising:
a processor to provide input image date; and
a display device to display an image based on the input image data,
wherein the display device comprises:
a display area comprising a first pixel comprising a first sub-pixel, a second sub-pixel, and a third sub-pixel;
a first light emitting element included in the first sub-pixel;
a second light emitting element included in the second sub-pixel; and
a third light emitting element included in the third sub-pixel,
wherein the first light emitting element comprises a (1-1)th electrode,
the second light emitting element comprises a (1-2)th electrode, and
the third light emitting element comprises a (1-3)th electrode, and
wherein the (1-1)th electrode is spaced apart from the (1-2)th electrode at a (2-1)th distance, and
the (1-2)th electrode is spaced apart from the (1-3)th electrode at a (2-2)th distance equal to the (2-1)th distance.
